(19) United States
(12) Patent Application Publication
(10) Pub. No.: US 2025/0356934 A1
(43) Pub. Date: Nov. 20, 2025

(54) DEFECTIVE WORD LINE BASED READ SCAN

(71) Applicant: Micron Technology, Inc., Boise, ID (US)

(72) Inventors: Lei Lin, Fremont, CA (US); Guang Hu, Mountain View, CA (US)

(21) Appl. No.: 19/192,141

(22) Filed: Apr. 28, 2025

Related U.S. Application Data
(60) Provisional application No. 63/647,357, filed on May 14, 2024.

(51) Int. Cl. G11C 29/02; G11C 16/34; G11C 29/00

(52) U.S. Cl. CPC G11C 29/022; G11C 16/349; G11C 29/76

(57) ABSTRACT

Systems and methods for providing a memory sub-system controller that selectively adjusts which word line groups of a memory sub-system to scan during a read scan. The controller obtains a map that identifies a set of portions of a set of memory components having a reliability value that falls below a reliability threshold. The controller determines that a condition for performing a read scan for a plurality of portions of the set of memory components has been met. The controller, in response to determining that the condition has been met, selectively performs the read scan on a subset of the plurality of portions of the set of memory components based on the map that identifies the set of portions having the reliability value that falls below the reliability threshold.

### PRIORITY APPLICATION

This application claims the benefit of priority to U.S. Provisional Application Ser. No. 63/647,357, filed May 14, 2024, which is incorporated herein by reference in its entirety.

### TECHNICAL FIELD

This disclosure relates generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIGS. 3 and 4 are block diagrams of examples of conditions for triggering a read scan, in accordance with some examples.

FIG. 5 is a flow diagram of an example method to selectively perform a read scan on memory components, in accordance with some examples.

FIG. 6 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

The present disclosure configures a system component, such as a memory sub-system controller, to perform selective read scans on a word line (WL), WL group (WLG), component, and/or sub-block basis and based on a defect map associated with a memory sub-system. The memory sub-system controller can access a map that identifies a portion or portions of the memory sub-system (e.g., portions of memory components) that have been determined to contain defects (e.g., for which a reliability value fails to transgress a reliability threshold). The controller can detect a condition for performing a read scan and can use the map to select which portions of the memory sub-system (e.g., which WLs, WLGs, components, and/or sub-blocks) to scan and which to skip. This ensures that performance of the memory system remains optimal, such as by restricting the number of portions for which a read scan is performed to only those portions known to be defective. This improves the overall efficiency of operating the memory sub-system.

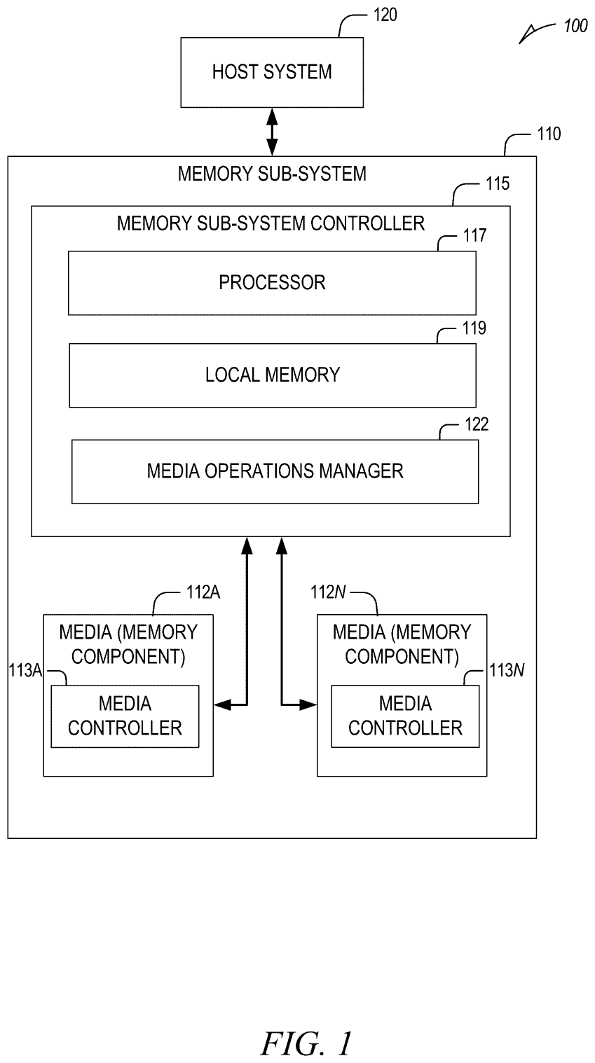

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data”.

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. Specifically, certain memory devices, such as NAND flash devices, include large die-by-die reliability (RWB) variation. As the technology for such memory devices continues to be scaled down, this die-by-die reliability variation becomes more pronounced and problematic in performing memory management. Current memory systems (e.g., SSD drive or die package systems) associate all of the memory devices or memory dies in the memory system with a certain reliability specification. Such reliability specifications can be set based on a read bit error rate (RBER) of different portions of the memory sub-system. In some cases, each block of each memory device is associated with a reliability grade or specification which is used to determine whether the block is a good block or a bad block. Good blocks are those that have reliability grades (e.g., RBER values) above a reliability threshold (e.g., above an RBER threshold) and bad blocks are blocks that have reliability grades below a reliability threshold. The reliability grades can be set at manufacture or during operation of the memory devices, such as by measuring the data retention and/or error rate associated with particular blocks, WLs, WLGs, and/or SBs.

Some media management operations include read scan operations. The read scan operations involve reading back data from certain WLs or sub-blocks (SBs) of the memory sub-system and verifying whether the data contains any errors. Certain systems perform these read scans each time a virtual block or superblock is closed. Such systems, though, experience poor performance given the long latency involved in reading back data from every WL or SB in the closed virtual block or superblock. To improve performance of these systems, the read can be performed after a threshold number of WLs or SBs are programmed with data. This adds some flexibility in managing when the read scan operations are performed but still involves the inefficient process of scanning every WL or SB in that threshold number of WLs or SBs. In order to further improve the efficiencies of performing the read scan operations, certain WLs or SBs can be skipped during the read scan. In such cases, when a threshold number of WLs or SBs are programmed, every other or every second other WL or SB in that threshold number is read back to detect read errors. Skipping such portions (e.g., WLs or SBs) in this random manner can result in inadvertently skipping performing read back operations for WLs or SBs that contain errors which results in poor memory performance. This creates significant inefficiencies and wastes resources.

Aspects of the present disclosure address the above and other deficiencies by providing a memory controller that can selectively and intelligently trigger performing read scan operations and selectively perform read scan operations on those portions that are known to have defects. Specifically, the memory sub-system controller can access a map that identifies a portion or portions of the memory sub-system (e.g., portions of memory components) that have been determined to contain defects (e.g., for which a reliability value fails to transgress a reliability threshold). The controller can detect a condition for performing a read scan and can use the map to select which portions of the memory sub-system (e.g., which WLs, WLGs, components, and/or sub-blocks) to scan and which to skip. This ensures that performance of the memory system remains optimal by restricting the number of portions for which read scan to those portions known to be defective. This improves the overall efficiency of operating the memory sub-system.

In some cases, the memory sub-system includes a three-dimensional (3D) NAND memory. The controller determines that a first portion of the plurality of portions is included in the set of portions of the set of memory components having the reliability value that falls below the reliability threshold. The controller performs the read scan on the first portion of the plurality of portions in response to determining that the first portion is included in the set of portions of the set of memory components having the reliability value that falls below the reliability threshold.

In some examples, the controller determines that a second portion of the plurality of portions is excluded from the set of portions of the set of memory components having the reliability value that falls below the reliability threshold. The controller skips performing the read scan on the second portion of the plurality of portions in response to determining that the second portion of the plurality of portions is excluded from the set of portions of the set of memory components having the reliability value that falls below the reliability threshold. In some cases, the reliability value includes a RBER, and the reliability threshold includes a minimum RBER.

The controller identifies a last portion of the set of memory components to which data has been programmed. The controller measures a number of previously programmed portions of the set of memory components that precede the last portion and determines that the condition is met in response to determining that the number of previously programmed portions transgresses a threshold value. The set of portions includes at least one of a set of WLs, WLGs, and/or sub-blocks.

In some examples, the controller determines that a last portion of the set of memory components to which data has been programmed is included in the set of portions of the set of memory components having the reliability value that falls below the reliability threshold. The controller measures a number of portions of the set of memory components that follow the last portion and determines that the condition is met in response to determining that the number of portions transgresses a minimum threshold value.

In some cases, the controller determines that one or more additional portions that follow the last portion are included in the set of portions of the set of memory components having the reliability value that falls below the reliability threshold. The controller measures a quantity portions in the one or more additional portions that follow the last portion and determines that the condition is met in response to determining that the quantity of portions transgresses a maximum value.

The controller determines that a die including the memory sub-system is part of a same lot or batch of dies for which a distribution of defects corresponding to the set of portions has been identified. The controller stores the map in association with the memory sub-system in response to determining that the die including the memory sub-system is part of the same lot or batch of dies for which the distribution of defects corresponding to the set of portions has been identified. The map can be stored in association with a set of lots. The map can be stored in association with a set of blocks.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed.

In some examples, the first memory component 112A including one or more portions (e.g., one or more WLs, one or more WLGs, one or more blocks, one or more SB, or one or more pages), or group of memory components including the first memory component 112A can be associated with a first reliability (capability) grade, value, measure, or lifetime PEC. The terms “reliability grade,” “value” and “measure” are used interchangeably throughout and can have the same meaning. The second memory component 112N (e.g., one or more WLs, one or more WLGs, one or more blocks, one or more SB, or one or more pages) or group of memory components including the second memory component 112N can be associated with a second reliability (capability) grade, value, measure, or lifetime PEC. In some examples, each memory component 112A to 112N can store respective configuration data that specifies the respective reliability grade and lifetime PEC and current PEC. In some examples, a memory or register can be associated with all of the memory components 112A to 112N and can store a table that maps different groups, bins or sets of the memory components 112A to 112N to respective reliability grades, lifetime PEC values, and/or current PEC values.

In some examples, a memory or register can be associated with all of the memory components 112A to 112N and can store a table or map that maps different WL, WLGs, SBs, and/or portions of the memory components 112A to 112N to reliability values that transgress a threshold. Namely, the memory or register can store a map that lists each WL, WLG, and/or SB that has been determined during manufacture to be defective (e.g., have a reliability value that fails to transgress a reliability threshold). In some cases, the table or map can be generated based on a distribution of errors or defects associated with a certain wafer, die sort, lot, or batch. A determination can be made that the memory sub-system 110 is part of a particular wafer, die sort, lot or batch and can then be loaded with the configuration data that includes the table or map associated with another memory sub-system 110 that is part of the same wafer, die sort, lot, or batch.

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-systems 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes a negative-and (NAND)-type flash memory and/or a 3D NAND flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells.

A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe and a single second row that spans a second set of the pages or blocks of the memory components 112A to 112N can correspond to or be grouped as a second block stripe.

The memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management, garbage collection operations, different near miss ECC operations, and/or different dynamic data refresh.

The memory sub-system controller 115 can include hardware such as one or more integrated circuits and/or discrete components, a buffer memory, or a combination thereof. The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some embodiments, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112N to 112N. The configuration data can describe the lifetime PEC values and/or reliability grades associated with different groups of the memory components 112N to 112N and/or different WLs, WLGs, and/or blocks within each of the memory components 112N to 112N. The configuration data can include a table that lists WLs, WLGs, and/or SBs that are known to be defective.

The memory sub-system controller 115 can be responsible for other memory management operations, such as wear leveling operations, garbage collection operations, error detection and error-correcting code (ECC) operations, encryption operations, caching operations, read scan, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some embodiments, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can selectively and intelligently trigger performing read scan operations and selectively perform read scan operations on those portions that are known to have defects. Specifically, the media operations manager 122 can access a map that identifies a portion or portions of the memory sub-system (e.g., portions of memory components) that have been determined to contain defects (e.g., for which a reliability value fails to transgress a reliability threshold). The media operations manager 122 can detect a condition for performing a read scan and can use the map to select which portions of the memory sub-system 110 (e.g., which WLs, WLGs, components, and/or sub-blocks) to scan and which to skip. This ensures that performance of the memory sub-system 110 remains optimal by restricting the number of portions for which read scan to those portions known to be defective. This improves the overall efficiency of operating the memory sub-system 110.

In some examples, the media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

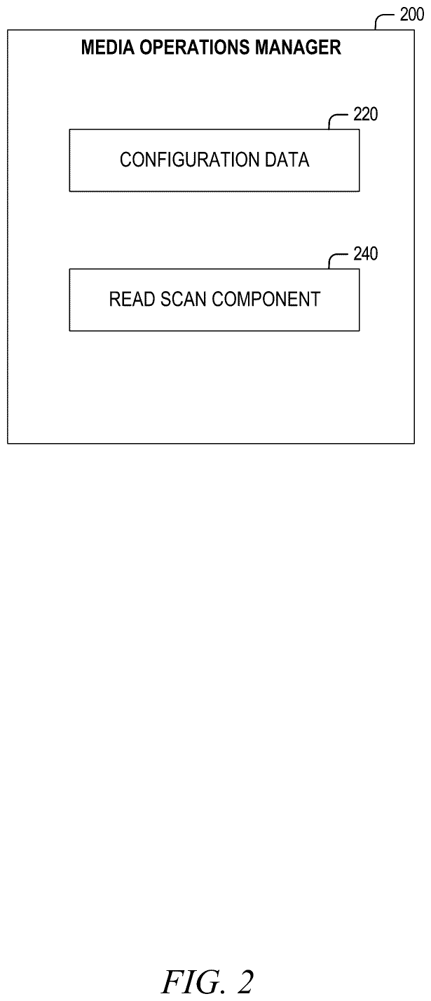

FIG. 2 is a block diagram of an example media operations manager 200 (corresponding to media operations manager 122 of FIG. 1), in accordance with some examples. As illustrated, the media operations manager 200 includes configuration data 220 and a read scan component 240. For some cases, the media operations manager 200 can differ in components or arrangement (e.g., less or more components) from what is illustrated in FIG. 2.

The configuration data 220 (e.g., configuration data component) accesses and/or stores configuration data associated with the memory components 112A to 112N of FIG. 1. In some examples, the configuration data 220 is programmed into the media operations manager 200. For example, the media operations manager 200 can communicate with the memory components 112A to 112N to obtain the configuration data and store the configuration data 220 locally on the media operations manager 122. In some examples, the media operations manager 122 communicates with the host system 120. The host system 120 receives input from an operator or user that specifies parameters including the list (or map) of different WLs, WLGs, bins, groups, blocks, block stripes, memory dies and/or sets of the memory components 112A to 112N that are defective (e.g., have a reliability value that fails to transgress a reliability threshold). The media operations manager 122 receives configuration data from the host system 120 of FIG. 1 and stores the configuration data in the configuration data 220. The configuration data 220 can store a table or map that identifies different WL, WLGs, and/or SBs of the memory components 112A to 112N that are defective.

In some examples, the read scan component 240 can monitor portions of the set of memory components 112A to 112N that are programmed. Namely, the read scan component 240 can keep track of the latest or last WL or SB that has been programmed with data. Based on the portions that are programmed, the read scan component 240 can determine whether a condition for performing or triggering a read scan is met. For example, the read scan component 240 can trigger performing a read scan when a certain number of WLs (e.g., 8 WL) are programmed with data. In such cases, the condition for triggering the read scan is met each time the certain number of WLs is programmed with data.

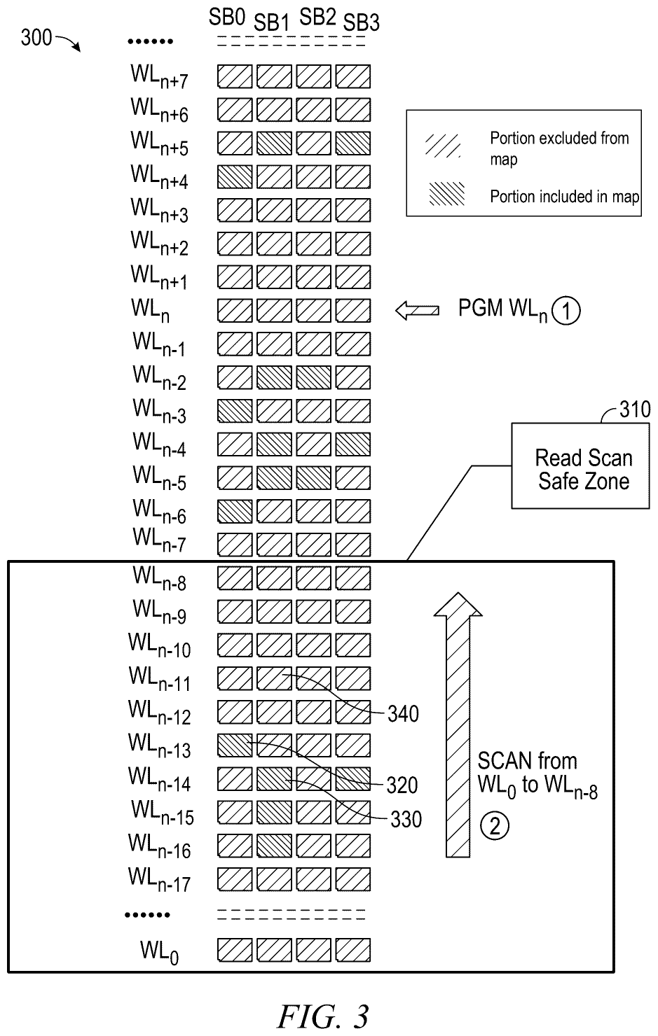

For example, as shown in the diagram 300 of FIG. 3, the read scan component 240 of FIG. 2 can count how many WLs have been programmed since the last read scan was performed. When the number of WLs reaches a threshold, the read scan component 240 defines a read scan safe zone 310. The read scan safe zone 310 includes a maximum number of WLs or minimum number of WLs to which data has recently been programmed (and can be part of an open block). The read scan component 240 can process the WLs or SBs (e.g., SB0-SB3) within the read scan safe zone 310 to perform a read scan. In such cases, the read scan component 240 identifies which WLs or SBs are in the read scan safe zone 310. The read scan component 240 compares the WLs or SBs that are in the read scan safe zone 310 to the map of defective portions stored in the configuration data 220.

For example, the read scan component 240 can determine that a first WL 320 is included or identified in the configuration data 220 as being defective. In such cases, the read scan component 240 can add the first WL 320 to a list of WLs of the read scan safe zone 310 for which the read scan is performed. Namely, the read scan component 240 can read data back from the first WL 320 and determine whether any read errors are encountered. As another example, the read scan component 240 can determine that one or more SBs 330 of another WL are included or identified in the configuration data 220 as being defective. In such cases, the read scan component 240 can add the one or more SBs 330 (and/or the WL that contains the one or more SBs 330) to a list of SBs or WLs of the read scan safe zone 310 for which the read scan is performed. Namely, the read scan component 240 can read data back from the one or more SBs 330 and determine whether any read errors are encountered.

The read scan component 240 can determine that a particular WL 340 (or set of WLs) in the read scan safe zone 310 are excluded or not found in the map of the configuration data 220. Namely, the read scan component 240 can search the map of defective WLs and/or SBs and determine that the particular WL 340 is not included or not found in the map. In response, the read scan component 240 can skip performing the read scan for the particular WL 340. Namely, the read scan component 240 can avoid reading data back from the particular WL 340 which reduces latency in completing the read scan operations. After performing the read scan in this manner, the read scan component 240 can generate another read scan safe zone 310 by waiting for an additional minimum threshold number of WLs or SBs to be programmed with data. The read scan component 240 can then process the additional minimum threshold number of WLs or SBs in a similar manner to perform selective read scan operations on certain WLs or SBs.

In some examples, the read scan component 240 can trigger the read scan operations dynamically based on whether a defective WL or SB is programmed with data. Namely, rather than waiting for a certain number of WLs or SBs to be programmed to determine that a condition for triggering the read scan is met, the read scan component 240 can intelligently trigger the read scan condition on the basis of what WL or SB is programmed.

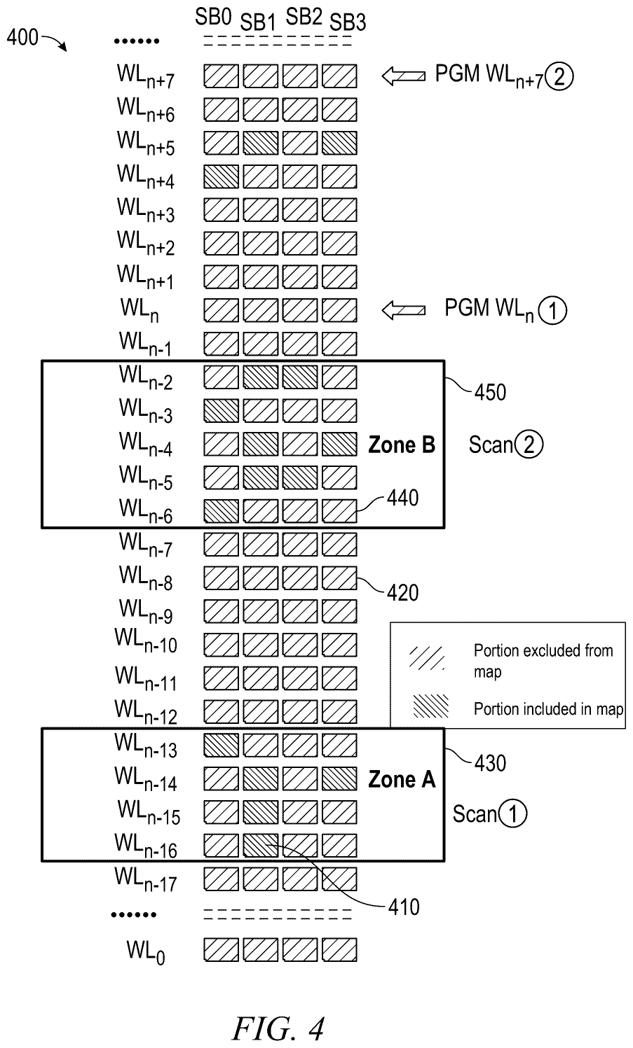

For example, the read scan component 240 can continue programming data into WLs or SBs without performing read scan operations until a WL or SB that is included on the map of defective WLs or SBs is programmed or encountered. Namely, as each WL or SB is programmed with data, the read scan component 240 compares the WL or SB to the map of defective memory portions. If the WL or SB is determined to be included in the list of defective memory portions (e.g., defective WLs, WLGs, and/or SBs), the read scan component 240 can begin creating a read scan zone. For example, as shown in the diagram 400 of FIG. 4, the read scan component 240 of FIG. 2 can determine that the SB 410 (or WLₙ₋₁₆) is currently being programmed and is included in the list of defective SBs or WLs on the map stored in the configuration data 220 of FIG. 2. In such cases, the read scan component 240 can measure how many more WLs or SBs have been programmed since the SB 410 was programmed with data. The read scan component 240 can determine that the number of additional WLs or SBs programmed since the SB 410 was programmed with data transgresses a minimum threshold value. In such cases, the read scan component 240 generates a first zone 430.

The read scan component 240 can then selectively perform a read scan only for those WLs or SBs in the first zone 430 that are in the list or map of defective memory portions stored in the configuration data 220. For example, the read scan component 240 can perform a read scan for the SB 410 because the SB 410 is included in the list of defective portions and can skip performing the read scan for another WL or SB that is not in the list of defective portions.

In some examples, the read scan component 240 can determine that a particular WL 440 has been programmed with data after another WL 420 was programed with data. The particular WL 440 can be determined to be on the list or map of defective WLs or SBs. In such cases, cases the read scan component 240 can begin tracking or forming a zone of WLs or SBs for which a read scan is performed after the particular WL 440 is programmed rather than when the WL 420 is programmed. This is because the WL 420 can be determined to be excluded from the list of defective WLs or SBs.

The read scan component 240 can start counting how many additional WLs or SBs that are included on the list or map of defective WLs are programmed with data after the particular WL 440 is programmed with data. The read scan component 240 can compare the number of additional WLs or SBs that are included on the list or map of defective WLs are programmed with data after the particular WL 440 is programmed with data to a maximum threshold value. The read scan component 240 can determine that the number of additional WLs or SBs that are included on the list or map of defective WLs are programmed with data after the particular WL 440 is programmed with data transgresses the maximum threshold value. The read scan component 240 generates a second zone 450 for performing a read scan. The second zone 450 includes the maximum threshold number of adjacent WLs or SBs that were programmed with data and that are each included in the list or map of defective WLs or SBs. In response, the read scan component 240 can then perform a read scan only for those WLs or SBs in the second zone 450.

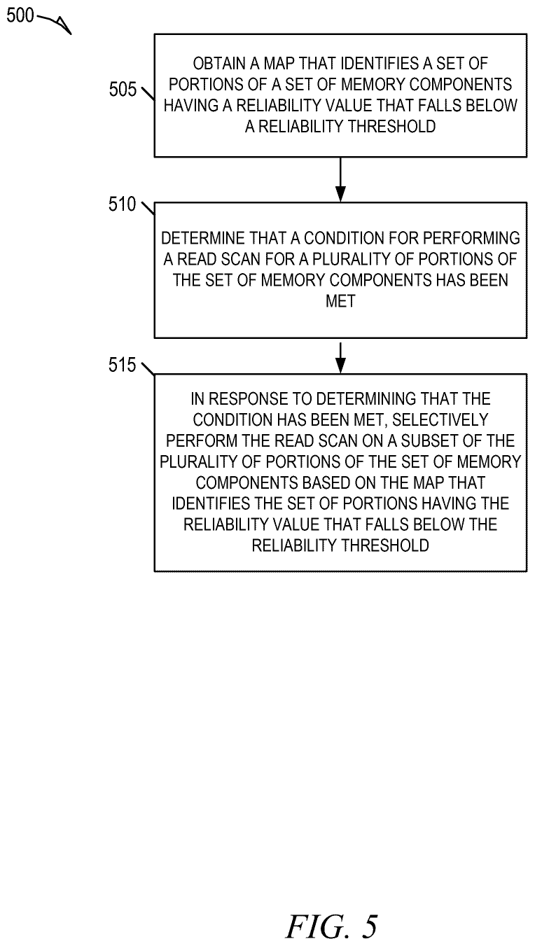

FIG. 5 is a flow diagram of an example method 500 (or process) to selectively perform read scan on memory components, in accordance with some examples. The method 500 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 500 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every examples. Other process flows are possible.

Referring now to FIG. 5, the method (or process) 500 begins at operation 505, with a media operations manager 122 of FIG. 1 of a memory sub-system (e.g., memory sub-system 110 of FIG. 1) obtaining a map that identifies a set of portions of a set of memory components having a reliability value that falls below a reliability threshold. Then, at operation 510, the media operations manager 122 of the memory sub-system determining that a condition for performing a read scan for a plurality of portions of the set of memory components has been met. Thereafter, at operation 515, the media operations manager 122, in response to determining that the condition has been met, selectively performs the read scan on a subset of the plurality of portions of the set of memory components based on the map that identifies the set of portions having the reliability value that falls below the reliability threshold.

In view of the disclosure above, various examples are set forth below. It should be noted that one or more features of an example, taken in isolation or combination, should be considered within the disclosure of this application.

Example 1: A system comprising: a set of memory components of a memory sub-system; and at least one processing device operatively coupled to the set of memory components, the at least one processing device being configured to perform operations comprising: obtaining a map that identifies a set of portions of the set of memory components having a reliability value that falls below a reliability threshold; determining that a condition for performing a read scan for a plurality of portions of the set of memory components has been met; and in response to determining that the condition has been met, selectively performing the read scan on a subset of the plurality of portions of the set of memory components based on the map that identifies the set of portions having the reliability value that falls below the reliability threshold.

Example 2. The system of Example 1, wherein the memory sub-system comprises a three-dimensional (3D) NAND memory.

Example 3. The system of any one of Examples 1-2, the operations comprising: determining that a first portion of the plurality of portions is included in the set of portions of the set of memory components having the reliability value that falls below the reliability threshold; and performing the read scan on the first portion of the plurality of portions in response to determining that the first portion is included in the set of portions of the set of memory components having the reliability value that falls below the reliability threshold.

Example 4. The system of Example 3, the operations comprising: determining that a second portion of the plurality of portions is excluded from the set of portions of the set of memory components having the reliability value that falls below the reliability threshold; and skipping performing the read scan on the second portion of the plurality of portions in response to determining that the second portion of the plurality of portions is excluded from the set of portions of the set of memory components having the reliability value that falls below the reliability threshold.

Example 5. The system of any one of Examples 1-4, wherein the reliability value comprises a read bit error rates (RBER), and wherein the reliability threshold comprises a minimum RBER.

Example 6. The system of any one of Examples 1-5, the operations comprising: identifying a last portion of the set of memory components to which data has been programmed; measuring a number of previously programmed portions of the set of memory components that precede the last portion; and determining that the condition is met in response to determining that the number of previously programmed portions transgresses a threshold value.

Example 7. The system of any one of Examples 1-6, wherein the set of portions comprises at least one of a set of word lines (WLs), WL groups (WLGs) or sub-blocks.

Example 8. The system of any one of Examples 1-7, the operations comprising: determining that a last portion of the set of memory components to which data has been programmed is included in the set of portions of the set of memory components having the reliability value that falls below the reliability threshold; measuring a number of portions of the set of memory components that follow the last portion; and determining that the condition is met in response to determining that the number of portions transgresses a minimum threshold value.

Example 9. The system of Example 8, the operations comprising: determining that one or more additional portions that follow the last portion are included in the set of portions of the set of memory components having the reliability value that falls below the reliability threshold; measuring a quantity portion in the one or more additional portions that follow the last portion; and determining that the condition is met in response to determining that the quantity of portions transgresses a maximum value.

Example 10. The system of any one of Examples 1-9, the operations comprising: determining that a die comprising the memory sub-system is part of a same lot or batch of dies for which a distribution of defects corresponding to the set of portions has been identified.

Example 11. The system of Example 10, the operations comprising: storing the map in association with the memory sub-system in response to determining that the die comprising the memory sub-system is part of the same lot or batch of dies for which the distribution of defects corresponding to the set of portions has been identified.

Example 12. The system of Example 11, wherein the map is stored in association with a set of lots.

Example 13. The system of any one of Examples 11-12, wherein the map is stored in association with a set of blocks.

Methods and computer-readable storage medium with instructions for performing any one of the above Examples.

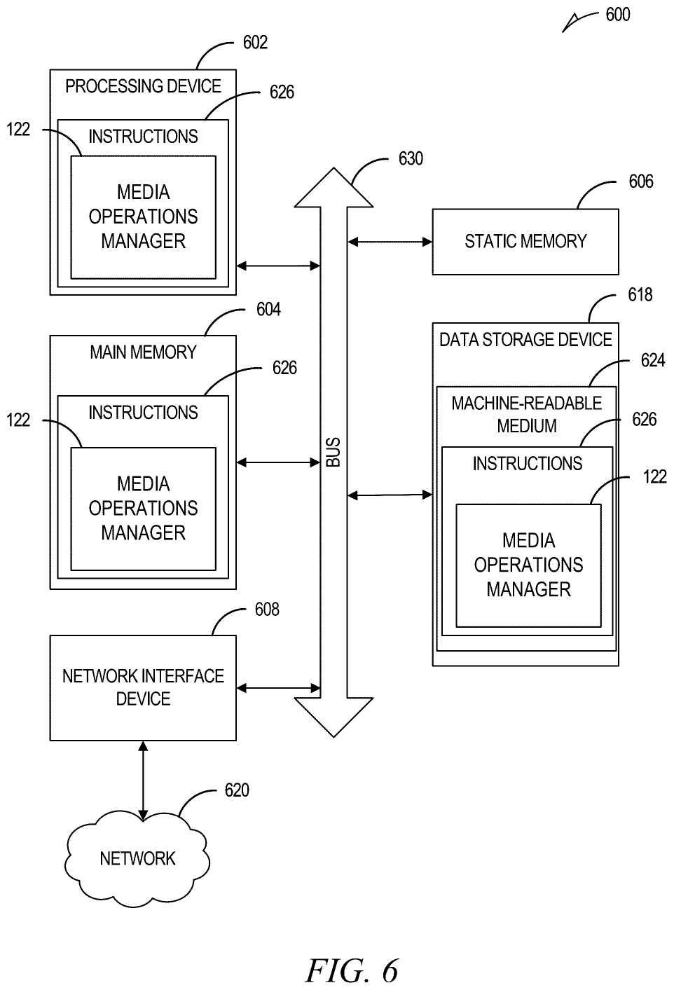

FIG. 6 illustrates an example machine in the form of a computer system 600 within which a set of instructions can be executed for causing the machine to perform any one or more of the methodologies discussed herein. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage device 618, which communicate with each other via a bus 630.

The processing device 602 represents one or more general-purpose processing devices such as a microprocessor, a central processing unit, or the like. More particularly, the processing device 602 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), a network processor, or the like. The processing device 602 is configured to execute instructions 626 for performing the operations and steps discussed herein. The computer system 600 can further include a network interface device 608 to communicate over a network 620.

The data storage device 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage device 618, and/or main memory 604 can correspond to the memory sub-system 110 of FIG. 1.

In one embodiment, the instructions 626 implement functionality corresponding to the media operations manager 122 of FIG. 1. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, embodiments of the disclosure have been described with reference to specific example embodiments thereof. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system;
at least one processing device operatively coupled to the set of memory components, the at least one processing device being configured to perform operations comprising:
obtaining a map that identifies a set of portions of the set of memory components having a reliability value that falls below a reliability threshold;
determining that a condition for performing a read scan for a plurality of portions of the set of memory components has been met; and
in response to determining that the condition has been met, selectively performing the read scan on a subset of the plurality of portions of the set of memory components based on the map that identifies the set of portions having the reliability value that falls below the reliability threshold.

2. The system of claim 1, wherein the memory sub-system comprises a three-dimensional (3D) NAND memory.

3. The system of claim 1, the operations comprising:
determining that a first portion of the plurality of portions is included in the set of portions of the set of memory components having the reliability value that falls below the reliability threshold; and
performing the read scan on the first portion of the plurality of portions in response to determining that the first portion is included in the set of portions of the set of memory components having the reliability value that falls below the reliability threshold.

4. The system of claim 3, the operations comprising:
determining that a second portion of the plurality of portions is excluded from the set of portions of the set of memory components having the reliability value that falls below the reliability threshold; and
skipping performing the read scan on the second portion of the plurality of portions in response to determining that the second portion of the plurality of portions is excluded from the set of portions of the set of memory components having the reliability value that falls below the reliability threshold.

5. The system of claim 1, wherein the reliability value comprises a read bit error rates (RBER), and wherein the reliability threshold comprises a minimum RBER.

6. The system of claim 1, the operations comprising:
identifying a last portion of the set of memory components to which data has been programmed;
measuring a number of previously programmed portions of the set of memory components that precede the last portion; and
determining that the condition is met in response to determining that the number of previously programmed portions transgresses a threshold value.

7. The system of claim 1, wherein the set of portions comprises at least one of a set of word lines (WLs), WL groups (WLGs) or sub-blocks.

8. The system of claim 1, the operations comprising:
determining that a last portion of the set of memory components to which data has been programmed is included in the set of portions of the set of memory components having the reliability value that falls below the reliability threshold;
measuring a number of portions of the set of memory components that follow the last portion; and
determining that the condition is met in response to determining that the number of portions transgresses a minimum threshold value.

9. The system of claim 8, the operations comprising:
determining that one or more additional portions that follow the last portion are included in the set of portions of the set of memory components having the reliability value that falls below the reliability threshold;
measuring a quantity portion in the one or more additional portions that follow the last portion; and
determining that the condition is met in response to determining that the quantity of portions transgresses a maximum value.

10. The system of claim 1, the operations comprising:
determining that a die comprising the memory sub-system is part of a same lot or batch of dies for which a distribution of defects corresponding to the set of portions has been identified.

11. The system of claim 10, the operations comprising:
storing the map in association with the memory sub-system in response to determining that the die comprising the memory sub-system is part of the same lot or batch of dies for which the distribution of defects corresponding to the set of portions has been identified.

12. The system of claim 11, wherein the map is stored in association with a set of lots.

13. The system of claim 11, wherein the map is stored in association with a set of blocks.

14. A method comprising:
obtaining a map that identifies a set of portions of a set of memory components having a reliability value that falls below a reliability threshold;
determining that a condition for performing a read scan for a plurality of portions of the set of memory components has been met; and
in response to determining that the condition has been met, selectively performing the read scan on a subset of the plurality of portions of the set of memory components based on the map that identifies the set of portions having the reliability value that falls below the reliability threshold.

15. The method of claim 14, wherein a memory sub-system comprising the set of memory components comprises a three-dimensional (3D) NAND memory.

16. The method of claim 14, comprising:
determining that a first portion of the plurality of portions is included in the set of portions of the set of memory components having the reliability value that falls below the reliability threshold; and
performing the read scan on the first portion of the plurality of portions in response to determining that the first portion is included in the set of portions of the set of memory components having the reliability value that falls below the reliability threshold.

17. The method of claim 16, comprising:
determining that a second portion of the plurality of portions is excluded from the set of portions of the set of memory components having the reliability value that falls below the reliability threshold; and
skipping performing the read scan on the second portion of the plurality of portions in response to determining that the second portion of the plurality of portions is excluded from the set of portions of the set of memory components having the reliability value that falls below the reliability threshold.

18. The method of claim 14, wherein the reliability value comprises a read bit error rates (RBER), and wherein the reliability threshold comprises a minimum RBER.

19. The method of claim 14, comprising:
identifying a last portion of the set of memory components to which data has been programmed;
measuring a number of previously programmed portions of the set of memory components that precede the last portion; and
determining that the condition is met in response to determining that the number of previously programmed portions transgresses a threshold value.

20. A non-transitory computer-readable storage medium comprising instructions that, when executed by at least one processing device, cause the at least one processing device to perform operations comprising:
obtaining a map that identifies a set of portions of a set of memory components having a reliability value that falls below a reliability threshold;
determining that a condition for performing a read scan for a plurality of portions of the set of memory components has been met; and
in response to determining that the condition has been met, selectively performing the read scan on a subset of the plurality of portions of the set of memory components based on the map that identifies the set of portions having the reliability value that falls below the reliability threshold.
